(19) United States
(12) Patent Application Publication
(10) Pub. No.: US 2008/0277786 A1
(43) Pub. Date: Nov. 13, 2008

(54) Semiconductor package substrate

(75) Inventors: Chun-Lung Chen, Taichung Hsien (TW); Yu-Po Wang, Taichung (TW); Jeng-Yuan Lai, Taichung Hsien (TW); Cheng-Hsu Hsiao, Taichung (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/156,874

(22) Filed: Jun. 5, 2008

(30) Foreign Application Priority Data
May 7, 2007 (TW) 096116051

(51) Int. Cl. H01L 23/48

(52) U.S. Cl. 257/738; 257/E23.021

(57) ABSTRACT

A semiconductor package substrate includes a body having an upper surface and a lower surface opposite to one another, a plurality of circuit layers formed in the body, a plurality of solder pads formed on the upper surface of the body, and a plurality of solder ball pads formed on the lower surface of the body. Each of the solder pads is electrically connected to one of the solder ball pads via the circuit layers and conductive structures disposed between the circuit layers, wherein the circuit layers and conductive structures are configured to expand outwardly in a fan-out manner so as to provide more space between the circuit layers closer to the lower surface of the body such that part of the solder pad-solder ball pad electrical connections can comprise a plurality of parallel connected conductive structures formed in the space, thereby enhancing the heat conducting passageway and the effect of heat-dissipation without having to dispose more solder pads on surface of the substrate.

### FIELD OF THE INVENTION

The present invention relates to semiconductor package substrates, and more particularly, to a semiconductor package substrate for use with flip chip ball grid array semiconductor packages.

### BACKGROUND OF THE INVENTION

The flip-chip ball grid array (FCBGA) semiconductor package is an advanced package structure characterized by comprising both a flip chip and a ball grid array, wherein an active surface of at least one chip is electrically connected to a surface of a substrate via a plurality of solder bumps in a flip-chip manner, and a plurality of solder balls are implanted on an opposite surface of the substrate to serve as input/output (I/O) connections. This package structure yields significant advantages to effectively decrease the package size, reduce resistance and improve electrical performances without using conventional bonding wires, thereby preventing decay of signals during transmission.

Referring to FIG. 1, U.S. Pat. No. 6,323,439 discloses a FCBGA semiconductor package for use in high-performance IC applications and comprising a large number of input/output (I/O) contacts for signal transmission. To facilitate effective signal transmission via the conventional substrate 10 adapted to carry the chip, the circuits of the substrate 10 are configured to expand outwardly from the upper surface thereof towards the low surface in a fan-out manner.

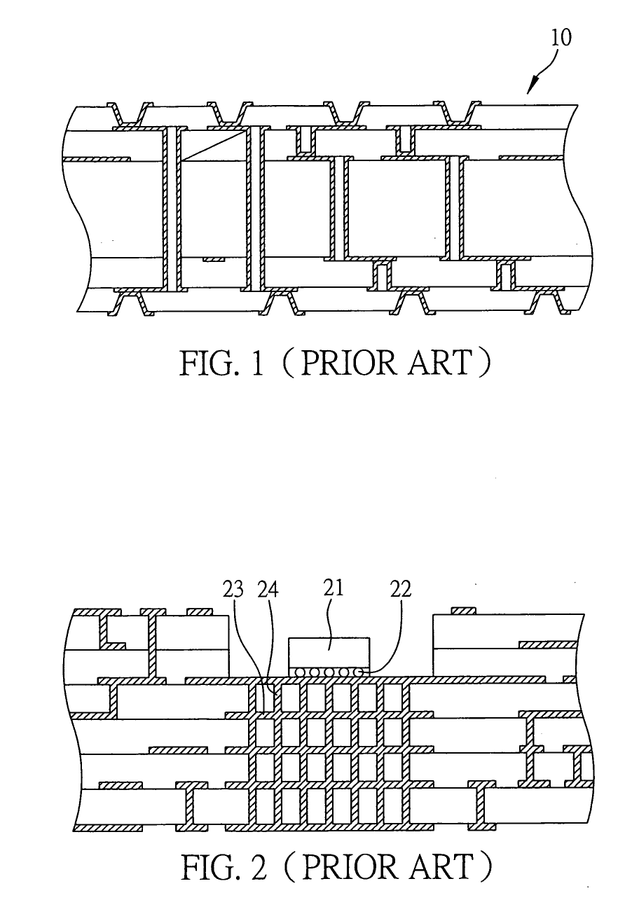

Complying with the trend of high integration in package structures and chips, however, there are pressing issues remain unsolved on the effective dissipation of massive heat generated from operation of package structures and chips. In view of this concern, there is disclosed in Japanese Patent Application No. JP9307238 a substrate structure for fast dissipation of heat generated in the flip-chip ball grid array (FCBGA) semiconductor packages, as shown in FIG. 2. As depicted in the drawing, a plurality of ground bumps 22 of the flip-chip chip 21 are electrically connected to the ground circuits disposed on the upper surface of the substrate, and then further electrically connected to ground circuits located on the lower surface of the substrate via multiple circuit layers 23 and conductive structures 24 disposed between layers of the substrate. Thereafter, the ground circuit of the substrate is electrically connected to external devices via a ground solder ball (not illustrated) implanted thereon, thereby allowing heat generated from operation of the flip-chip chip 21 to pass through the substrate and be conducted and transmitted to the outside for dissipation.

Obviously, the need for efficient and improved heat-dissipation within the chip is escalating and becomes pressing as the number of I/O contacts becomes greater and greater on a single FC chip, particularly when the spacing between the I/O contacts becomes narrower and narrower, it is difficult, if not impossible, to increase ground wires on the limited surface of the substrate for facilitating heat-dissipation. This limiting factor in terms of the substrate size further hinders the capability and improvement of heat-dissipation within the chip.

As such, there exits a need to provide an improved substrate structure that facilitates efficient heat-dissipation within the chip to ensure quality of fabricated package products.

### SUMMARY OF THE INVENTION

A primary objective of the present invention is to provide a semiconductor package substrate having an enhanced heat-conducting passageway by configuring the circuits thereof in a fan-out manner to achieve an optimal heat-dissipation effect.

Another objective of the present invention is to provide a semiconductor package substrate that is not bound by the configuration of ground wires on the surface of the substrate and has an enhanced heat-conducting passageway for optimal heat-dissipation.

To achieve the above and other objectives, the present invention proposes a semiconductor package substrate that comprises: a body having an upper surface and a lower surface opposite to one another; a plurality of circuit layers formed in the body; a plurality of solder pads formed on the upper surface of the body; and a plurality of solder ball pads formed on the lower surface of the body, each of the solder pads being electrically connected to one of the solder ball pads via the circuit layers and conductive structures disposed between the circuit layers, wherein a part of the electrical connections between the solder pads and the solder ball pads comprise a plurality of conductive structures in parallel connection provided between at least two adjacent circuit layers so as to increase passageways for heat dissipation, thereby enhancing heat-dissipation efficiency.

The conductive structures disposed between the circuit layers may be in the form of, for example, a conductive via. The solder pads formed on the upper surface of the semiconductor package substrate body comprise signal solder pads and ground solder pads. The solder ball pads formed on the lower surface of the semiconductor package substrate body comprise signal solder ball pads and ground solder ball pads, wherein the ground solder pads are electrically connected to the ground solder ball pads via the circuit layers and the parallel-connected conductive structures to serve as a heat-conducting passageway.

Thereafter, a plurality of conductive bumps formed on the active surface of the flip-chip type chip are mounted on and electrically connected to the solder pads formed on the semiconductor package substrate body. The conductive bumps comprise signal bumps and ground bumps, wherein the ground bumps are mounted on the ground solder pads of the semiconductor package substrate, and are further electrically connected to the ground solder ball pads via the circuit layers and the parallel-connected conductive structures formed between the circuit layers, thereby conducting heat generated from operation of the chip to the outside via ground solder balls implanted on the ground solder ball pads.

Moreover, since the substrate circuits are configured to expand outwardly from the upper surface thereof to the lower surface in a fan-out manner in the present invention, a plurality of parallel-connected conductive structures may be formed between circuit layers at positions located closer to the lower surface of the substrate, such that the heat-conducting passageway is enhanced for optimal heat-dissipation without increasing the number of ground pads on the surface of the substrate.

### BRIEF DESCRIPTION OF THE GETTINGINGS

The present invention can be more fully understood by reading the following detailed description of the preferred embodiments, with reference made to the accompanying drawings, wherein:

FIG. 1 (PRIOR ART) illustrates a cross sectional perspective view of the FCBGA semiconductor package disclosed by U.S. Pat. No. 6,323,439;

FIG. 2 (PRIOR ART) illustrates a cross sectional perspective view of the Flip-Chip semiconductor package disclosed by Japanese Pat. No. JP9307238;

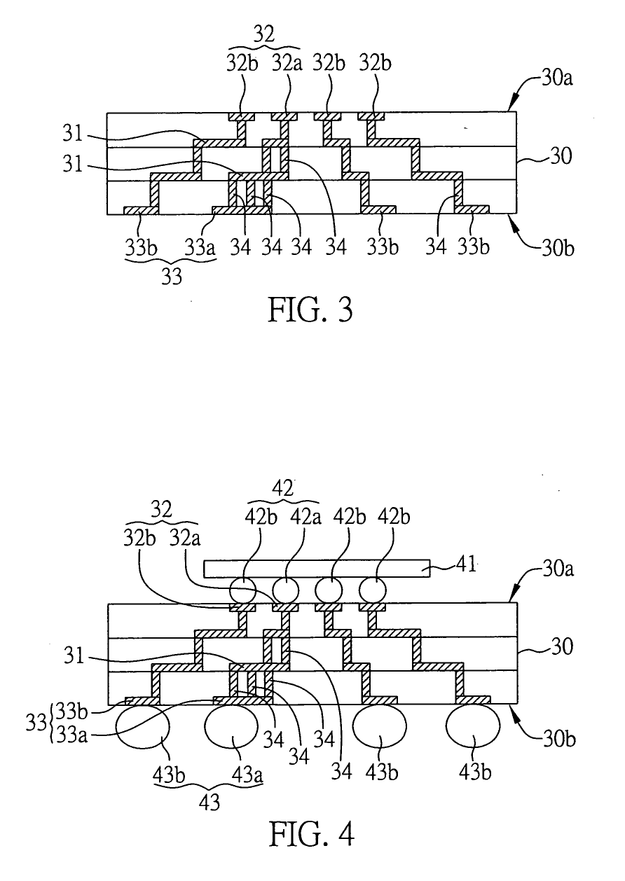

FIG. 3 illustrates a cross sectional perspective view of a semiconductor package substrate according to the present invention; and

FIG. 4 illustrates a perspective view of a semiconductor package incorporating the semiconductor package substrate according to the present invention.

### DETAILED DESCRIPTION OF THE PREFERRED EMBODIMENTS

The present invention is described in the following so that one skilled in the pertinent art can easily understand other advantages and effects of the present invention. Note that the drawings provided herein are all simplified perspective views illustrating the basic structure of the present invention and the components applied are not limited to what is shown in the preferred embodiments. The present invention may also be implemented and applied according to other embodiments, and the details may be modified based on different views and applications without departing from the spirit of the invention.

FIG. 3 illustrates a cross sectional perspective view of a semiconductor package substrate according to the present invention. The semiconductor package substrate comprises a body 30 having an upper surface 30a and a lower surface 30b opposite to one another, a plurality of circuit layers 31 formed in the body 30; a plurality of solder pads 32 formed on the upper surface 30a of the body 30; and a plurality of solder ball pads 33 formed on the lower surface 30b of the body 30. Each of the solder pads 32 is electrically connected to each solder ball pad 33 respectively via the circuit layers 31 and conductive structures 34 formed between the circuit layers, wherein part of the solder pad-solder ball pad electrical connections comprise a plurality of conductive structures 34 in parallel connection provided between at least two adjacent circuit layers 31 for enhancing the heat-conducting passageway.

For effective transmission of the ever-complicating I/O signals of the chip, the circuit layers 31 and conductive structures 34 of the semiconductor package substrate body 30 are configured to expand outwardly from the upper surface 30a of the body 30 to the lower surface 30b thereof in a fan-out manner, thereby facilitating transmission of I/O signals of the chip mounted on the upper surface 30a of the semiconductor package substrate body 30.

According to one aspect of the present invention, the solder pads 32 mounted on the upper surface 30a of the semiconductor package substrate body 30 comprise signal solder pads 32b for transmitting I/O signals of the chip and ground solder pads 32a for grounding the chip and conducting heat generated therefrom. The solder ball pads 33 mounted on the lower surface 30b of the body 30 comprise signal solder ball pads 33b and ground solder ball pads 33a. Each of the signal solder pads 32b is electrically connected to each signal solder ball pad 33b respectively through the circuit layers 31 and conductive structures 34 formed between the circuit layers (such as conductive vias), wherein each signal solder pad-signal solder ball pad electrical connection comprises only one conductive structure 34 disposed corresponding to every two adjacent circuit layers 31 so as to achieve vertical electrical transmission, thereby avoiding short circuit.

Relatively, the ground solder pads 32a are electrically connected to the corresponding ground solder ball pads 33a respectively through the circuit layers 31 and conductive structures 34 disposed between the circuit layers. As the circuit layers 31 and conductive structures 34 that are formed between the circuit layers are configured to expand outwardly from the upper surface 30a of the substrate body 30 towards the lower surface 30b thereof in a fan-out manner, there exists larger space in layers closer to the lower surface 30b of the body 30, such that a plurality of conductive structures 34 in parallel connection can be formed therein, and also the number of conductive structures 34 that can be disposed between adjacent circuit layers 31 closer to the lower surface 30b of the body 30 is larger than the number of the conductive structures 34 in parallel connection that can be disposed between adjacent circuit layers 31 farther away from the lower surface 30b of the body 30, thereby enhancing the heat-conducting passageway and the effect of heat-dissipation without having to dispose more ground pads on the surface of the substrate body 30.

Referring to FIG. 4, a flip-chip type chip 41 is then mounted on and electrically connected to solder pads 32 on the upper surface 30a of the substrate body 30 via conductive bumps 42. The conductive bumps 42 include signal bumps 42b and ground bumps 42a, wherein the signal bumps 42b are mounted on the signal solder pads 32b and the ground bumps 42a are mounted on the ground solder pads 32a. Furthermore, a plurality of solder balls 43 are further mounted on the solder ball pads 33 respectively on the lower surface 30b of the substrate body 30, wherein the solder balls 43 comprise signal solder balls 43b mounted on the signal solder ball pads 33b and ground solder balls 43a mounted on the ground solder ball pads 33a.

By the foregoing configuration, heat generated from operation of the flip-chip type chip 41 can be effectively transmitted to the outside via the ground bumps 42a, the ground solder pads 32a of the semiconductor package substrate, the circuit layers 31 formed in the substrate body 30 and conductive structures 34 formed between layers thereof, and the ground solder ball pads 33a and the ground solder balls 43a. Specifically, the circuit fan-out configuration employed in the substrate body 30 makes more room available at positions closer to the lower surface 30b of the body 30, such that a plurality of parallel-connected conductive structures 34 can be formed between circuit layers 31, thereby enhancing the heat-conducting passageway and the effect of heat-dissipation without having to dispose more ground pads on the surface of the substrate body 30.

Accordingly, the semiconductor package substrate proposed by the present invention enables flip-chip type chips to be mounted on and electrically connected to the solder pads via conductive bumps formed thereon, wherein the conductive bump includes signal bumps and ground bumps, the ground bumps being mounted on the ground solder pads of the semiconductor package substrate for electrically connecting to the ground solder ball pads via circuit layers and the parallel-connected conductive structures formed between layers, and finally via the ground solder balls implanted on the ground solder pads so as to transmit heat generated from the chip to the outside.

In conclusion, the characteristic of the present invention lies in the fan-out configuration of the circuits being expanded outwardly from the upper surface of the substrate towards the lower surface thereof, so as to obtain more space on layers located closer to the lower surface of the body for allowing parallel-connected conductive structures to be formed between circuit layers, thereby enhancing the heat-conducting passageway and the effect of heat-dissipation without having to dispose more ground pads on the surface of the substrate.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package substrate, comprising:
a body having an upper surface and a lower surface;
a plurality of circuit layers formed in the body;
a plurality of solder pads formed on the upper surface of the body; and
a plurality of solder ball pads formed on the lower surface of the body, each of the solder pads being electrically connected to a corresponding one of the solder ball pads via the circuit layers and conductive structures disposed between the circuit layers, wherein a part of the electrical connections between the solder pads and the solder ball pads comprise a plurality of conductive structures in parallel connection provided between at least two adjacent circuit layers, so as to increase passageways for heat dissipation.

2. The semiconductor package substrate of claim 1, wherein the circuit layers and conductive structures are configured to expand outwardly from the upper surface of the body towards the lower surface of the body in a fan-out manner.

3. The semiconductor package substrate of claim 2, wherein the circuit layers and conductive structures are configured to expand outwardly from the upper surface of the body towards the lower surface of the body in a fan-out manner such that more space can be provided between circuit layers closer to the lower surface of the body for disposing of the parallel-connected conductive structures.

4. The semiconductor package substrate of claim 1, wherein the solder pads formed on the upper surface of the semiconductor package substrate body comprise signal solder pads and ground solder pads, and the solder ball pads formed on the lower surface of the semiconductor package substrate body comprise signal solder ball pads and ground solder ball pads.

5. The semiconductor package substrate of claim 4, wherein the signal solder pads are electrically connected to the corresponding signal solder ball pads respectively through the circuit layers and conductive structures formed between the circuit layers, wherein each signal solder pad-signal solder ball pad electrical connection comprises only one conductive structure disposed corresponding to every two adjacent circuit layers so as to achieve vertical electrical transmission.

6. The semiconductor package substrate of claim 4, wherein the ground solder pads are electrically connected to the corresponding ground solder ball pads via the circuit layers and the conductive structures disposed between the circuit layers, wherein the circuit layers and conductive structures are configured in a fan-out manner such that more space can be provided between the circuit layers closer to the lower surface of the body for disposing of the parallel-connected conductive structures.

7. The semiconductor package substrate of claim 6, wherein the number of the parallel-connected conductive structures that can be disposed between adjacent circuit layers closer to the lower surface of the body is larger than the number of the parallel-connected conductive structures that can be disposed between adjacent circuit layers farther away from the lower surface of the body.

8. The semiconductor package substrate of claim 4, wherein solder balls are further mounted on the solder ball pads, the solder balls comprising signal solder balls mounted on the signal solder ball pads and ground solder balls mounted on the ground solder ball pads.

9. The semiconductor package substrate of claim 1, wherein a flip-chip type chip is mounted on and electrically connected to the solder pads formed on the upper surface of the semiconductor package substrate body via a plurality of conductive bumps.

10. The semiconductor package substrate of claim 9, wherein the conductive bumps comprise signal bumps and ground bumps, and the solder pads comprise signal solder pads and ground solder pads, the signal bumps being mounted on the signal solder pads and the ground bumps being mounted on the ground solder pads.

11. The semiconductor package substrate of claim 1, wherein the conductive structures formed between the circuit layers are conductive vias.
